(19) United States
(12) Patent Application Publication
(10) Pub. No.: US 2021/0125965 A1
(43) Pub. Date: Apr. 29, 2021

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventor: Wen-Long LU, Kaohsiung (TW)

(73) Assignee: Advanced Semiconductor Engineering, Inc., Kaohsiung (TW)

(21) Appl. No.: 16/663,084

(22) Filed: Oct. 24, 2019

(51) Int. Cl. H01L 25/065; H01L 23/31; H01L 23/13; H01L 23/538; H01L 23/00; H01L 25/00; H01L 21/48; H01L 21/56

(52) U.S. Cl. CPC H01L 25/0657; H01L 2225/06586; H01L 23/13; H01L 23/5383; H01L 23/5386; H01L 24/13; H01L 24/16; H01L 25/50; H01L 21/4853; H01L 21/4857; H01L 21/568; H01L 21/565; H01L 2224/16237; H01L 2224/13083; H01L 2224/13144; H01L 2224/13139; H01L 2224/13147; H01L 2224/13155; H01L 2224/13166; H01L 2224/13184; H01L 2225/06517; H01L 2225/06555; H01L 23/3107

(57) ABSTRACT

A semiconductor device package includes a dielectric layer and a patterned conductive layer disposed in the dielectric layer. The dielectric layer has a first surface, a second surface opposite the first surface, and a third surface extended from the first surface to the second surface. The semiconductor device package also includes a first electronic component in direct contact with the first surface of the dielectric layer and a first connection structure disposed between the first electronic component and the patterned conductive layer. A method of manufacturing a semiconductor device package is also disclosed.

### BACKGROUND

### 1. Technical Field

The present disclosure generally relates to a semiconductor device package and a method of manufacturing the same.

### 2. Description of the Related Art

A semiconductor device package can have a semiconductor device attached or bonded to a substrate by connection elements (e.g. solder). As demand of input/output (I/O) quantity arises, shrinkage in both pitch and dimension of the I/O (e.g. conductive pads or bond pads) are specified, which may result in a short-circuit (or bridge) issue if solder on one I/O is forced to be in contact with solder on another I/O when bonding the semiconductor device to the substrate by heat and compression technique(s).

### SUMMARY

In one or more embodiments, a semiconductor device package includes a dielectric layer and a patterned conductive layer disposed in the dielectric layer. The dielectric layer has a first surface, a second surface opposite the first surface, and a third surface extended from the first surface to the second surface. The semiconductor device package also includes a first electronic component in direct contact with the first surface of the dielectric layer and a first connection structure disposed between the first electronic component and the patterned conductive layer.

In one or more embodiments, a semiconductor device package includes a dielectric layer and a patterned conductive layer disposed in the dielectric layer. The dielectric layer has a first surface, a second surface under the first surface, and a third surface extended from the first surface to the second surface. The semiconductor device package also includes a first electronic component disposed on the first surface of the dielectric layer and a first connection structure disposed between the first electronic component and the patterned conductive layer. The first connection structure is disposed between the first surface and the second surface of the dielectric layer.

In one or more embodiments, a method of manufacturing a semiconductor package includes providing a carrier and forming a seed layer on the carrier. The method further includes forming a connection structure on the carrier. The connection structure is surrounded by the seed layer. The method further includes forming a dielectric layer on the carrier to surround the seed layer and removing the seed layer.

### BRIEF DESCRIPTION OF THE DRAWINGS

Aspects of the present disclosure are readily understood from the following detailed description when read with the accompanying figures. It should be noted that various features may not be drawn to scale. The dimensions of the various features may be arbitrarily increased or reduced for clarity of discussion.

FIG. 1 illustrates a perspective view of a semiconductor device package in accordance with some embodiments of the present disclosure.

FIG. 2 illustrates a top view of a semiconductor device package in accordance with some embodiments of the present disclosure.

FIG. 3 illustrates a cross-sectional view of a semiconductor device package in accordance with some embodiments of the present disclosure.

FIG. 4A illustrates an enlarged view of a portion of the semiconductor device package in accordance with some embodiments of the present disclosure.

FIG. 4B illustrates an enlarged view of a portion of the semiconductor device package in accordance with some embodiments of the present disclosure.

FIG. 4C illustrates an enlarged view of a portion of the semiconductor device package in accordance with some embodiments of the present disclosure.

FIG. 4D illustrates an enlarged view of a portion of the semiconductor device package in accordance with some embodiments of the present disclosure.

FIG. 4E illustrates an enlarged view of a portion of the semiconductor device package in accordance with some embodiments of the present disclosure.

FIG. 5 illustrates a cross-sectional view of a semiconductor device package in accordance with some embodiments of the present disclosure.

FIG. 6A is a schematic illustration showing topography of a dielectric layer in accordance with some embodiments of the present disclosure.

FIG. 6B is a schematic illustration showing topography of a dielectric layer in accordance with some embodiments of the present disclosure.

FIG. 6C is a schematic illustration showing topography of a dielectric layer in accordance with some embodiments of the present disclosure.

FIG. 6D is a schematic illustration showing topography of a dielectric layer in accordance with some embodiments of the present disclosure.

FIG. 7A illustrates one or more stages of a method of manufacturing a semiconductor device package in accordance with some embodiments of the present disclosure.

FIG. 7B illustrates one or more stages of a method of manufacturing a semiconductor device package in accordance with some embodiments of the present disclosure.

FIG. 7C illustrates one or more stages of a method of manufacturing a semiconductor device package in accordance with some embodiments of the present disclosure.

FIG. 7D illustrates one or more stages of a method of manufacturing a semiconductor device package in accordance with some embodiments of the present disclosure.

FIG. 7E illustrates one or more stages of a method of manufacturing a semiconductor device package in accordance with some embodiments of the present disclosure.

FIG. 7F illustrates one or more stages of a method of manufacturing a semiconductor device package in accordance with some embodiments of the present disclosure.

FIG. 7G illustrates one or more stages of a method of manufacturing a semiconductor device package in accordance with some embodiments of the present disclosure.

FIG. 7H illustrates one or more stages of a method of manufacturing a semiconductor device package in accordance with some embodiments of the present disclosure.

FIG. 7I illustrates one or more stages of a method of manufacturing a semiconductor device package in accordance with some embodiments of the present disclosure.

FIG. 7J illustrates one or more stages of a method of manufacturing a semiconductor device package in accordance with some embodiments of the present disclosure.

FIG. 7K illustrates one or more stages of a method of manufacturing a semiconductor device package in accordance with some embodiments of the present disclosure.

FIG. 7L illustrates one or more stages of a method of manufacturing a semiconductor device package in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. Besides, the present disclosure may repeat reference numerals and/or letters in the various examples. This repetition is for simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts. The specific embodiments discussed are merely illustrative and do not limit the scope of the disclosure.

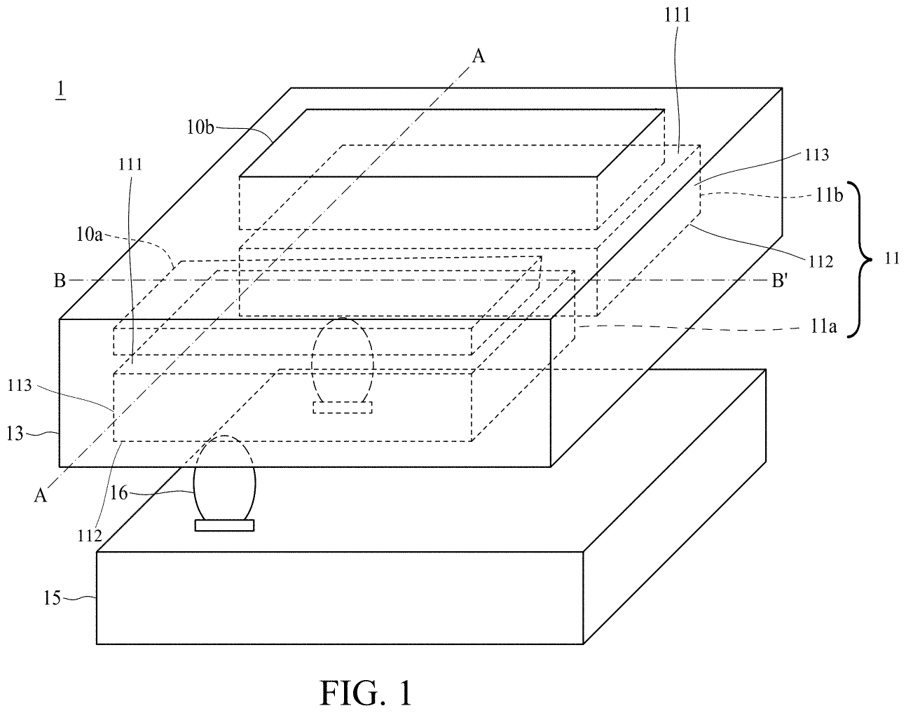

FIG. 1 illustrates a perspective view of a semiconductor device package in accordance with some embodiments of the present disclosure.

Referring to FIG. 1, the semiconductor device package 1 may include electronic components 10a and 10b, dielectric layers 11a and 11b, an encapsulation layer 13, a substrate 15 and an electrical contact 16.

The dielectric layer 11a may include, for example, but is not limited to, one or more organic materials (e.g., phosphoric anhydride (PA), a polyimide (PI), a polybenzoxazole (PBO), an epoxy, and an epoxy-based material), or one or more inorganic materials (e.g., silicon, a glass, a ceramic, and an oxide). The dielectric layer 11a maybe include connection structures, interconnections, redistribution structure and/or circuitry (not denoted in FIG. 1) disposed therein.

The connection structures in the dielectric layer 11a can include some conductive elements, for example, but is not limited to, conductive trace(s), pad(s), contact(s), via(s). The connection structures may be, or may include, for example, but is not limited to, a conductive material such as a metal or metal alloy. Examples include gold (Au), silver (Ag), aluminum (Al), copper (Cu), or other metal or alloy thereof.

The connection structures in the dielectric layer 11a can have a pitch equal to or less than approximately 12 micrometers (μm). The connection structures in the dielectric layer 11a can have a line width/space equal to or less than approximately 12/12 μm. The connection structures in the dielectric layer 11a can have a pitch equal to or less than approximately 10 μm. The connection structures in the dielectric layer 11a can have a line width/space equal to or less than approximately 10/10 μm. The connection structures in the dielectric layer 11a can have a pitch equal to or less than approximately 8 μm. The connection structures in the dielectric layer 11a can have a line width/space equal to or less than approximately 8/8 μm. The connection structures in the dielectric layer 11a can have a pitch equal to or less than approximately 5 μm. The connection structures in the dielectric layer 11a can have a line width/space equal to or less than approximately 5/5 μm. The connection structures in the dielectric layer 11a can have a pitch equal to or less than approximately 2 μm. The connection structures in the dielectric layer 11a can have a line width/space equal to or less than approximately 2/2 μm.

The dielectric layer 11a can include a surface 111, another surface 112 opposite the surface 111, and a lateral surface 113 extended from the surface 111 to the surface 112.

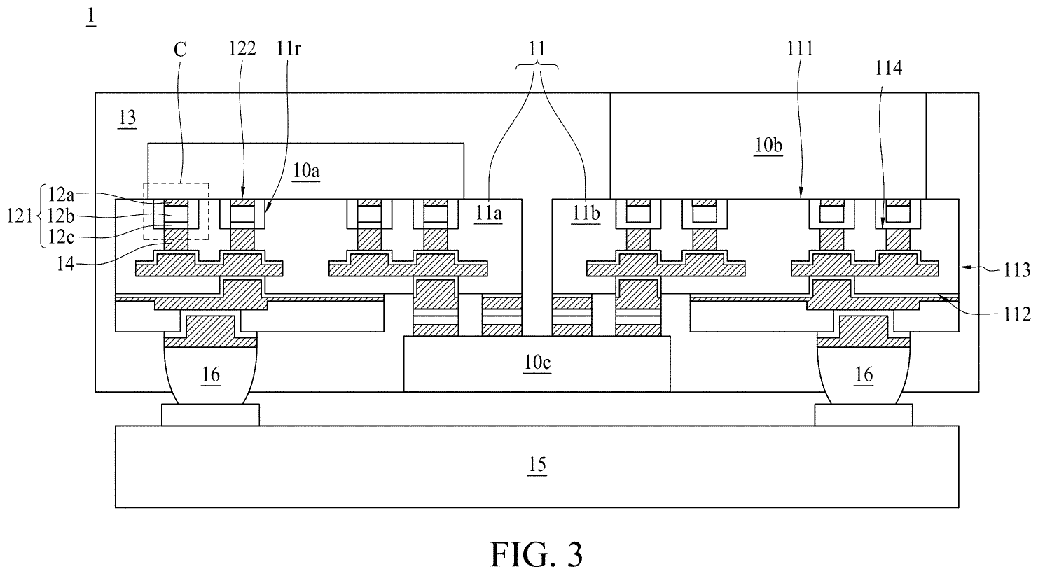

Another dielectric layer 11b may be the same or similar to the dielectric layer 11a. The dielectric layer 11b can include connection structures, interconnections, redistribution structure and/or circuitry (not denoted in FIG. 1) disposed therein. The dielectric layer 11b can include a surface 111, another surface 112 opposite the surface 111, and a lateral surface 113 extended from the surface 111 to the surface 112 (such as denoted in FIG. 3). The dielectric layers 11a and 11b can be collectively referred to dielectric layer 11.

The electronic component 10a can be disposed on the surface 111 of the dielectric layer 11a. The electronic component 10a can have an active surface facing to the surface 111 of the dielectric layer 11a, and a back surface (also referred to as backside) opposite the active surface.

The electronic component 10a may be, for example, but is not limited to, a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. The electronic component 10a can be electrically connected to the connection structures in the dielectric layer 11a.

The electronic component 10a can be bonded or attached to the surface 111 of the dielectric layer 11a. The electronic component 10a can be bonded or attached to the connection structures in the dielectric layer 11a.

The electronic component 10a can be in direct contact with the surface 111 of the dielectric layer 11a. The electronic component 10a can be in direct contact with the connection structures in the dielectric layer 11a.

Another electronic component 10b can be disposed on the surface 111 of the dielectric layer 11b. The electronic component 10b may be the same or similar to the electronic component 10a. The electronic component 10b may be different from the electronic component 10a. The electronic component 10b can be electrically connected to the connection structures in the dielectric layer 11b.

The electronic component 10b can be bonded or attached to the surface 111 of the dielectric layer 11b. The electronic component 10b can be bonded or attached to the connection structures in the dielectric layer 11b.

The electronic component 10b can be in direct contact with the surface 111 of the dielectric layer 11b. The electronic component 10b can be in direct contact with the connection structures in the dielectric layer 11b.

Although FIG. 1 illustrates a stack of two electronic components 10a and 10b and two dielectric layers 11a and 11b, it is contemplated that the stack as shown in FIG. 1 can include more or fewer electronic components and more or fewer dielectric layers.

The encapsulation layer 13 can encapsulate or cover the electronic component 10a. The encapsulation layer 13 can encapsulate or cover the electronic component 10b. The encapsulation layer 13 can encapsulate or cover the dielectric layer 11a. The encapsulation layer 13 can encapsulate or cover the dielectric layer 11b.

The encapsulation layer 13 may include, for example, but is not limited to, one or more organic materials (e.g., a molding compound, bismaleimide triazine (BT), a PI, a PBO, a solder resist, an Ajinomoto build-up film (ABF), a polypropylene (PP), an epoxy-based material, or a combination of two or more thereof), inorganic materials (e.g., silicon, a glass, a ceramic, a quartz, or a combination of two or more thereof), liquid-film material(s) or dry-film material(s), or a combination of two or more thereof.

In some embodiments, the electronic component 10a can be entirely encapsulated by the encapsulation layer 13. In some embodiments, the electronic component 10b can be partially exposed through the encapsulation layer 13. For example, the top surface of the electronic component 10b can be exposed through the encapsulation layer 13.

The lateral surface 113 of the dielectric layer 11a can be encapsulated by the encapsulation layer 13. The lateral surface 113 of the dielectric layer 11a can be in contact with the encapsulation layer 13.

The lateral surface 113 of the dielectric layer 11b can be encapsulated by the encapsulation layer 13. The lateral surface 113 of the dielectric layer 11b can be in contact with the encapsulation layer 13.

Encapsulating the electronic components 10a and 10b, and the dielectric layers 11a and 11b with the encapsulation layer 13 in the same operation may mitigate warpage issue, which may improve reliability of the semiconductor device packages.

The electrical contact 16 (e.g. a solder ball) can be disposed on the dielectric layer 11a. The electrical contact 16 can be disposed on the dielectric layer 11b. The electrical contact 16 can provide electrical connections between the connection structures in the dielectric layer 11a and the substrate 15 (or other external components, e.g., external circuits or circuit boards). The electrical contact 16 can provide electrical connections between the connection structures in the dielectric layer 11b and the substrate 15.

In some embodiments, the electrical contact 16 may include, for example, but is not limited to, a controlled collapse chip connection (C4) bump, a ball grid array (BGA) or a land grid array (LGA). In some embodiments, the number of electrical contacts can be varied due to design change.

The substrate 15 may include, for example, but is not limited to, a printed circuit board, such as a paper-based copper foil laminate, a composite copper foil laminate, or a polymer-impregnated glass-fiber-based copper foil laminate. The substrate 15 may include an interconnection structure, such as a redistribution layer (RDL) or a grounding element.

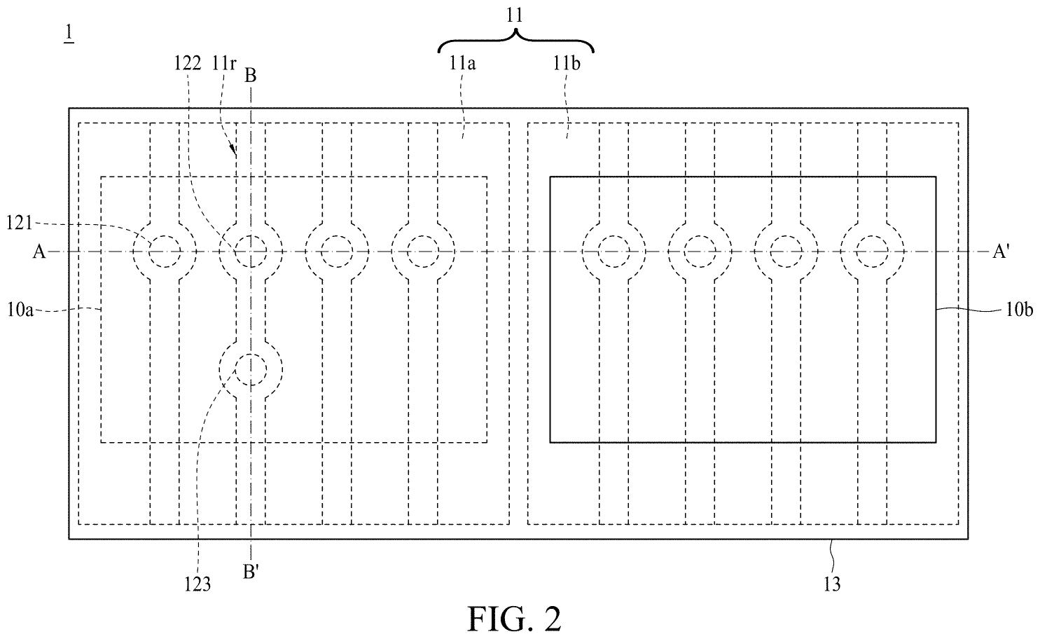

FIG. 2 illustrates a top view of the semiconductor device package in accordance with some embodiments of the present disclosure.

For example, FIG. 2 may illustrate a top view of the semiconductor device package 1 in FIG. 1.

Referring to FIG. 2, the dielectric layer 11 can have one or more channels or recesses 11r.

The connection structures (such as the connection structure 121, 122, and 123) can be disposed within the recesses 11r. The encapsulation layer 13 (or other encapsulation material(s)) can be filled in the recesses 11r to surround or encapsulate the connection structures, so no empty space would be observed in the recesses 11r.

The connection structures (such as the connection structure 121, 122, and 123) can be disposed within the dielectric layers 11a and 11b. The connection structures (such as the connection structure 121, 122, and 123) can be received within the recesses 11r.

The connection structures (such as the connection structure 121, 122, and 123) can be disposed adjacent to each other.

Two of the connection structures (such as the connection structures 121 and 122) can be disposed in different recesses 11r. Two of the connection structures (such as the connection structures 121 and 122) can be disposed in recesses 11r that are not physically connected. Two of the connection structures (such as the connection structures 121 and 122) can be disposed in different recesses 11r. Two of the connection structures (such as the connection structures 121 and 122) can be disposed in individual recesses 11r.

Two of the connection structures (such as the connection structures 121 and 122) can be isolated or spaced apart by the dielectric layer 11. For example, the connection structure 121 can be received in the left-most recess 11r as illustrated in FIG. 2, and the connection structure 122 can be received in another recess. The connection structure 121 and the connection structure 122 can be received in different recesses, with a part of the dielectric layer 11 disposed therebetween. Therefore, bridge issue (e.g. solder or other connection material flows from the connection structure 121 to the connection structure 122, or vice versa) can be avoided when bonding the electronic component 10a to the connection structures in the dielectric layer 11a by heat and compression technique(s). Therefore, no short-circuit issue occurs between the connection structure 121 and the connection structure 122.

Two of the connection structures (such as the connection structures 122 and 123) can be disposed in the same recess 11r. For example, the connection structure 122 and the connection structure 123 can be received in the same recess 11r. The recess 11r provides fluid communication between the connection structure 122 and the connection structure 123. The fluid communication may help to flow the encapsulation layer 13 (or other encapsulation material(s)) to surround the connection structure 122 and the connection structure 123 in the same operation. The distance between the connection structure 122 and the connection structure 123 may be designed such that no bridge will be formed therebetween when bonding the electronic component 10a to the connection structures in the dielectric layer 11a by heat and compression technique(s).

The encapsulation layer 13 (or other encapsulation material(s)) can surround the connection structure 121. The encapsulation layer 13 (or other encapsulation material(s)) can surround the connection structure 122. The encapsulation layer 13 (or other encapsulation material(s)) can surround the connection structure 123. The encapsulation material in the recess 11r can have the same material as the encapsulation layer 13 out of the recess 11r. The encapsulation material in the recess 11r can have a material different from the encapsulation layer 13 out of the recess 11r.

It is contemplated that the dimensions of the units or components as illustrated in FIG. 2 (e.g., the relative widths, the relative diameters, and the relative lengths) can be varied due to design change.

FIG. 3 illustrates a cross-sectional view of the semiconductor device package in accordance with some embodiments of the present disclosure.

For example, FIG. 3 may illustrate a cross-sectional view of the semiconductor device package 1 along the line AA′ as illustrated in FIGS. 1 and 2.

Referring to FIG. 3, the dielectric layer 11 can have a surface 114 and a side surface (or a sidewall) extended from the surface 111 to the surface 114. The surface 114 and the sidewall extended from the surface 111 to the surface 114 can define the recess 11r in the dielectric layer 11.

The connection structures (such as the connection structures 121 and 122) can be disposed on the surface 114 of the dielectric layer 11 (that is, the bottom surface of the recess 11r). The connection structures (such as the connection structures 121 and 122) can be disposed under the surface 111 of the dielectric layer 11. The connection structures (such as the connection structures 121 and 122) can be disposed between the surface 114 of the dielectric layer 11 and the surface 111 of the dielectric layer 11.

The connection structures (such as the connection structures 121 and 122) can have a surface substantially coplanar with the surface 111 of the dielectric layer 11. The connection structures (such as the connection structures 121 and 122) can have a surface substantially aligned with the surface 111 of the dielectric layer 11.

The electronic components (such as the electronic components 10a and 10b) can have a surface substantially coplanar with the surface 111 of the dielectric layer 11. The electronic components (such as the electronic components 10a and 10b) can have a surface substantially aligned with the surface 111 of the dielectric layer 11.

The coplanar surface of the connection structures (such as the connection structures 121 and 122) and the dielectric layer 11 can be in contact with the electronic component 10a.

An interface between the dielectric layer 11 and the electronic components (such as the electronic components 10a and 10b) can be observed.

The electronic components can be bonded to a level defined by the dielectric layer 11. With the dielectric layer 11 set the predefined height of the connection structures (that is, the predefined distance between the electronic components and the surface 114 of the dielectric layer 11), the coplanarity of the bonding structure can be improved. For example, when attaching or bonding the electronic components on the dielectric layer 11, the electronic components can be landed on a level defined by the dielectric layer 11, and variation in the height of the connection structure between the electronic components and the dielectric layer 11 will not affect the coplanarity therebetween.

The connection structure 121 can include a layer 12c stacked on a conductive layer 14 in the dielectric layer 11, a layer 12b stacked on the layer 12c, and a layer 12a stacked on the layer 12b. The layer 12a may be a solder. The layer 12b may be a soldering layer. The layer 12b may include Au, Ag, Cu, or other metal or alloy thereof. The layer 12c may be a barrier layer. The layer 12c may include nickel (Ni), titanium (Ti), tungsten (W), or other metal or alloy thereof. Although FIG. 3 illustrates a stack of three layers 12a, 12b, and 12c, it is contemplated that the stack as illustrated in FIG. 3 can include more or fewer layers, and each connection structure can include more or fewer layers.

The conductive layer 14 (or an interconnection, a redistribution structure and/or circuitry) can be disposed in the dielectric layer 11. The conductive layer 14 can be disposed below the connection structures (such as the connection structures 121 and 122).

The conductive layer 14 can be patterned. Portions of the conductive layer 14 can be exposed through the surface 114 of the dielectric layer 11. The conductive layer 14 can provide electrical connections between the connection structures (such as the connection structures 121 and 122) and the electrical contact 16.

Electronic component 10c can be attached or bonded to the surface 112 of the dielectric layer 11 through, for example, but is not limited to, flip-chip bond technique. A projected area of the electronic component 10c can be shifted from a projected area of the electronic component 10a (and/or the electronic component 10b). For example, the projected area of the electronic component 10c can be not overlapped with the projected area of the electronic component 10a (and/or the electronic component 10b). For example, the projected area of the electronic component 10c can be partially overlapped with the projected area of the electronic component 10a (and/or the electronic component 10b).

The relative positions of the projected areas of the electronic components may be changed of interest. For example, the arrangement of electronic components 10a, 10b and 10c as shown in FIG. 3 can mitigate or alleviate warpage issue.

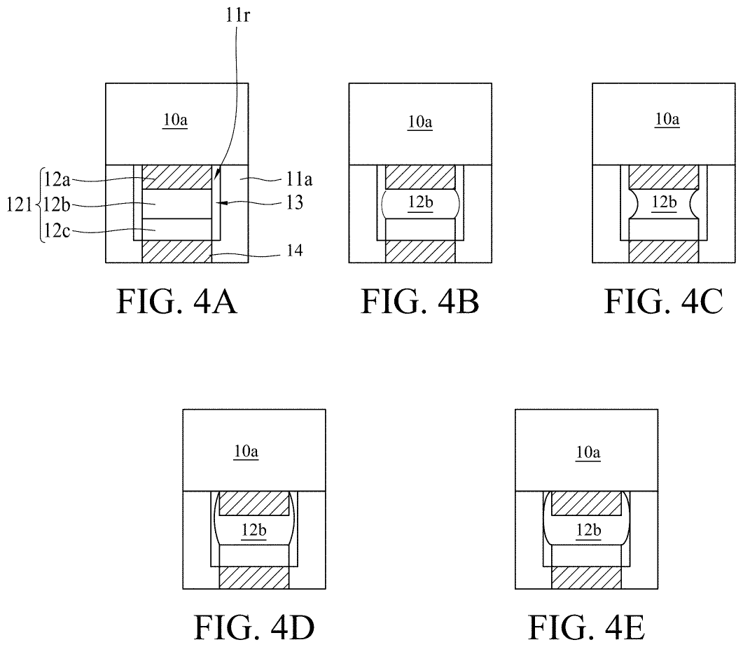

FIG. 4A, FIG. 4B, FIG. 4C, FIG. 4D, and FIG. 4E illustrate enlarged views of a portion of the semiconductor device package in accordance with some embodiments of the present disclosure.

For example, a portion of the semiconductor device package 1 in a dotted circle C as illustrated in FIG. 3 can be replaced with the structures as illustrated in FIG. 4A, FIG. 4B, FIG. 4C, FIG. 4D, and FIG. 4E.

Referring to FIG. 4A, the sidewall (or the lateral surface) of the layer 12b can be substantially coplanar with the sidewall of the layer 12a and/or the sidewall of the layer 12c. The sidewall of the layer 12b can be substantially aligned with the sidewall of the layer 12a and/or the sidewall of the layer 12c. For example, the width of the connection structure 121 can be substantially constant.

Referring to FIG. 4B, the sidewall of the layer 12b can be protruded from the sidewall of the layer 12a. The sidewall of the layer 12b can be protruded from the sidewall of the layer 12c. The width of the layer 12b can be substantially greater than the width of the layer 12a. The width of the layer 12b can be substantially greater than the width of the layer 12c. A minimum width of the layer 12b can be substantially greater than the width of the layer 12a. A minimum width of the layer 12b can be substantially greater than the width of the layer 12c. A width of the layer 12b can be substantially equal to the width of the layer 12a. A width of the layer 12b can be substantially equal to the width of the layer 12c.

Referring to FIG. 4C, the sidewall of the layer 12b can be recessed with respect to the sidewall of the layer 12a and/or the sidewall of the layer 12c. The width of the layer 12b can be substantially less than the width of the layer 12a. The width of the layer 12b can be substantially less than the width of the layer 12c. The maximum width of the layer 12b can be substantially less than the width of the layer 12a. The maximum width of the layer 12b can be substantially less than the width of the layer 12c. A width of the layer 12b can be substantially equal to the width of the layer 12a. A width of the layer 12b can be substantially equal to the width of the layer 12c.

Referring to FIG. 4D and FIG. 4E, the layer 12b can protruded from the sidewall of the layer 12a and/or the sidewall of the layer 12c, and flow on the sidewall of the layer 12a. The layer 12b can surround the sidewall of the layer 12a.

As mentioned, the electronic components (such as the electronic component 10a in FIG. 3) is bonded on the connection structures (such as the connection structure 121 in FIG. 3) by applying heat and compression technique(s) in, for example, a reflow operation. The layer 12b (or the soldering layer) may flow onto the surface of the layer 12a, since the attraction force of the material of the layer 12a may be bigger for the material of the layer 12b, in comparison with the attraction force of the material of the layer 12c. Therefore, an excess part of the layer 12b on the layer 12a may be observed.

However, with the connection structure 121 received in the recess 11r defined in the dielectric layer 11a, the layer 12b will not flow out of the recess 11r, and will not form bridge with another connection structure. Therefore, the reliability of the semiconductor device package can be improved.

The connection structure 121 can be spaced apart from the sidewall of the recess 11r, such as shown in FIG. 4A, FIG. 4B, FIG. 4C and FIG. 4D. The connection structure 121 in FIG. 4A, FIG. 4B, FIG. 4C and FIG. 4D is surrounded by the encapsulation layer 13, and further surrounded by the sidewall of the recess 11r.

The connection structure 121 can be in contact with the sidewall of the recess 11r, such as shown in FIG. 4E. The connection structure 121 in FIG. 4E flows on the layer 12a, and flows to contact the sidewall of the recess 11r. The encapsulation layer 13 fills the other space in the recess 11r.

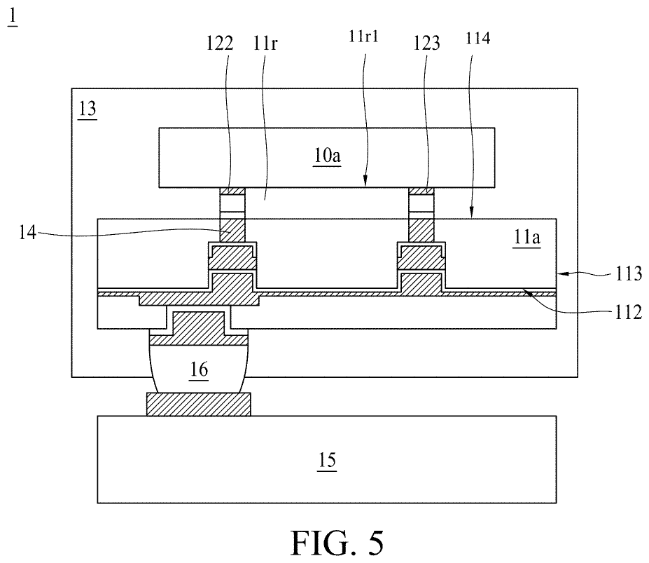

FIG. 5 illustrates a cross-sectional view of a semiconductor device package in accordance with some embodiments of the present disclosure.

For example, FIG. 5 may illustrate a cross-sectional view of the semiconductor device package 1 along the line BB′ as illustrated in FIGS. 1 and 2.

Referring to FIG. 5, the recess 11r can have a surface 11r1 substantially coplanar with a surface of the electronic component 10a. The surface 11r1 can be substantially coplanar with the surface 111 (not denoted in FIG. 5) of the dielectric layer 11a.

The surface 11r1 can be exposed from the dielectric layer 11a. An exposed surface of the encapsulation layer 13 can be in contact with the electronic component 10a.

In some embodiments, the encapsulation material(s) in the recess 11r can be different from the encapsulation layer 13, and an interface can be observed therebetween. In some embodiments, the encapsulation material(s) in the recess 11r can be the same or similar to the encapsulation layer 13.

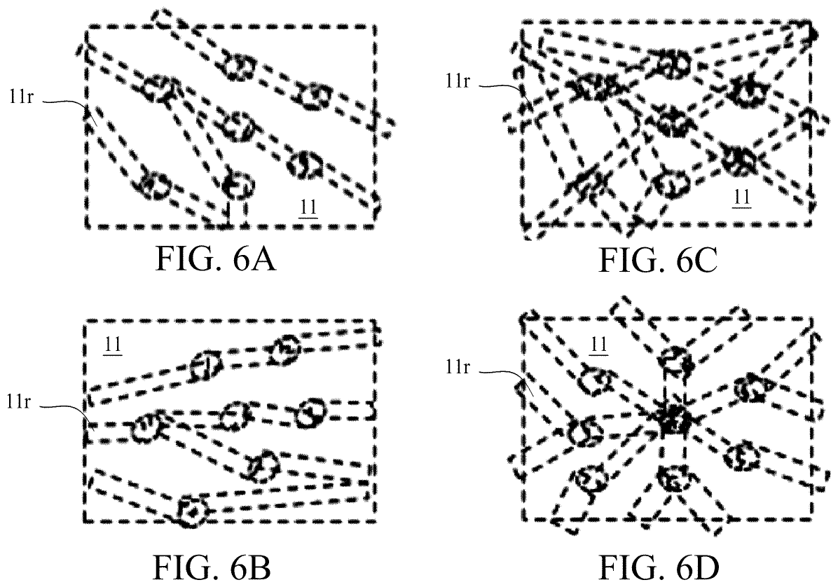

FIG. 6A, FIG. 6B, FIG. 6C and FIG. 6D are schematic illustrations showing topography of a dielectric layer in accordance with some embodiments of the present disclosure.

For example, the dielectric layer 11 (e.g., the dielectric layers 11a and/or 11b) in FIG. 2 can be replaced with the dielectric layers as illustrated in FIG. 6A, FIG. 6B, FIG. 6C and FIG. 6D.

Referring to FIG. 6A, the recesses 11r in FIG. 6A can form a substantially 45-degree angle with a side of the dielectric layer 11.

Referring to FIG. 6B, the recesses 11r in FIG. 6B can be substantially parallel with a side of the dielectric layer 11. The recesses 11r in FIG. 6A can be quicker to be filled with encapsulation material (such as the encapsulation layer 13 in FIG. 1) in comparison with the recesses 11r in FIG. 6B. However, the recesses 11r in FIG. 6A can be also inclined to form bubbles in comparison with the recesses 11r in FIG. 6B, if the flow rate is too fast.

Referring to FIG. 6C, the recesses 11r in FIG. 6C can cross with each other. The recesses 11r in FIG. 6C can form a checkerboard pattern or a checkerboard-like pattern.

Referring to FIG. 6D, the recesses 11r in FIG. 6D can form a radial pattern. The recesses 11r in FIG. 6D can be directed toward sides of the dielectric layer 11 from a central point. The recesses 11r in FIG. 6D can be quicker to be filled in comparison with the recesses 11r in FIGS. 6A, 6B, and 6C. However, the recesses 11r in FIG. 6D can be also inclined to form bubbles in comparison with the recesses 11r in FIGS. 6A, 6B, and 6C.

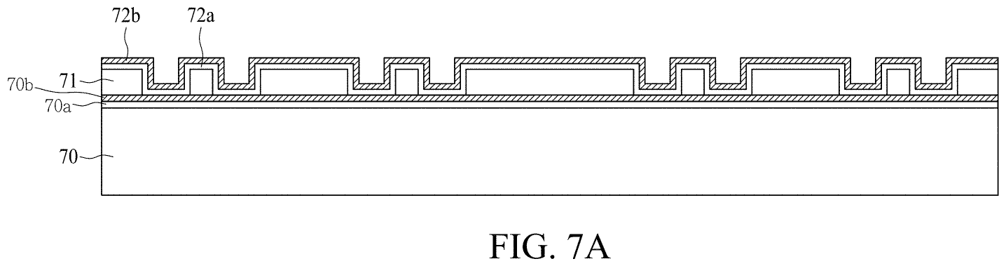

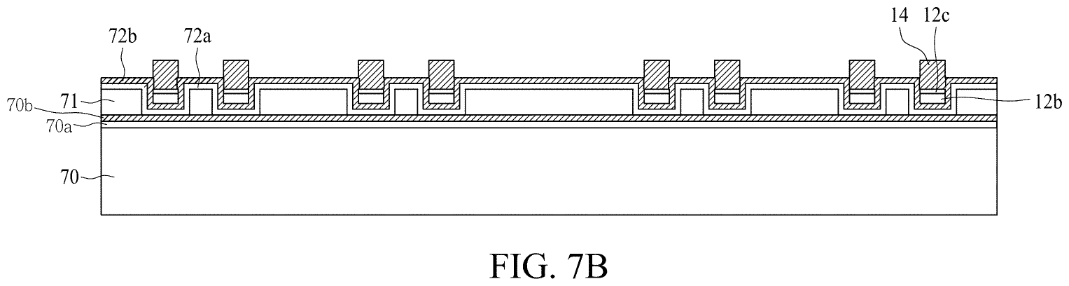

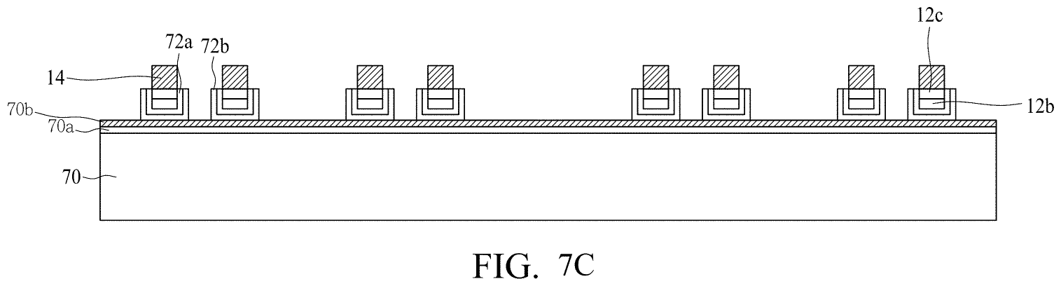

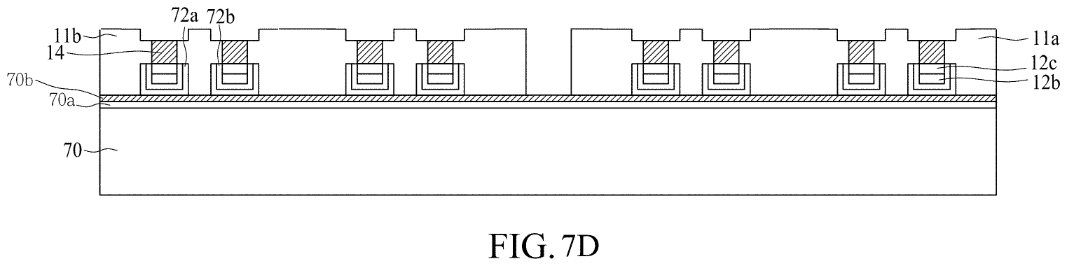

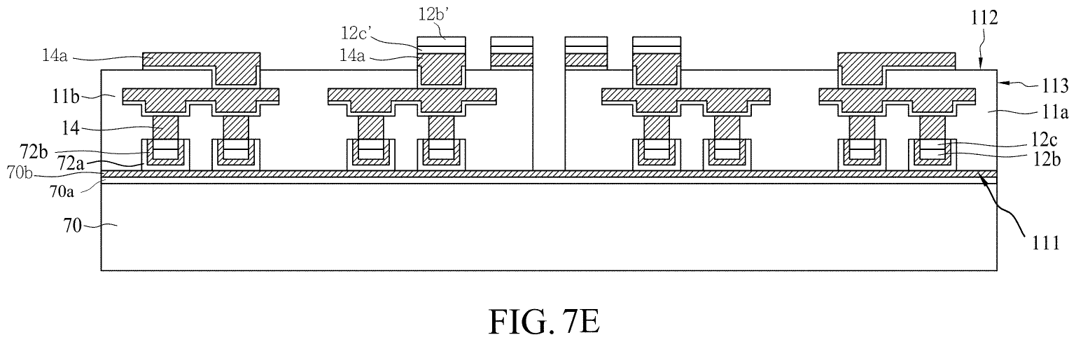

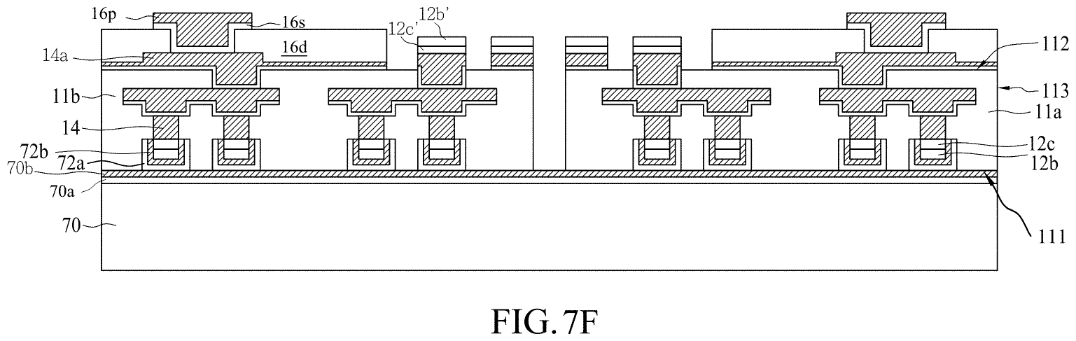

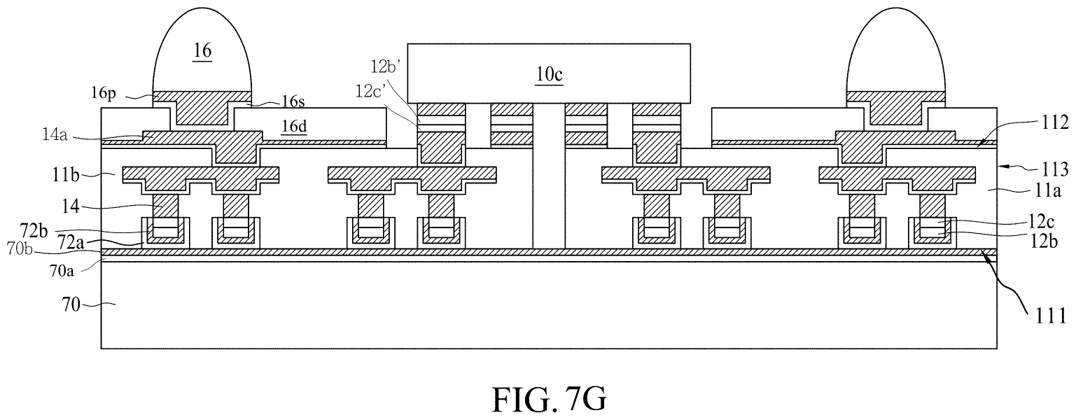

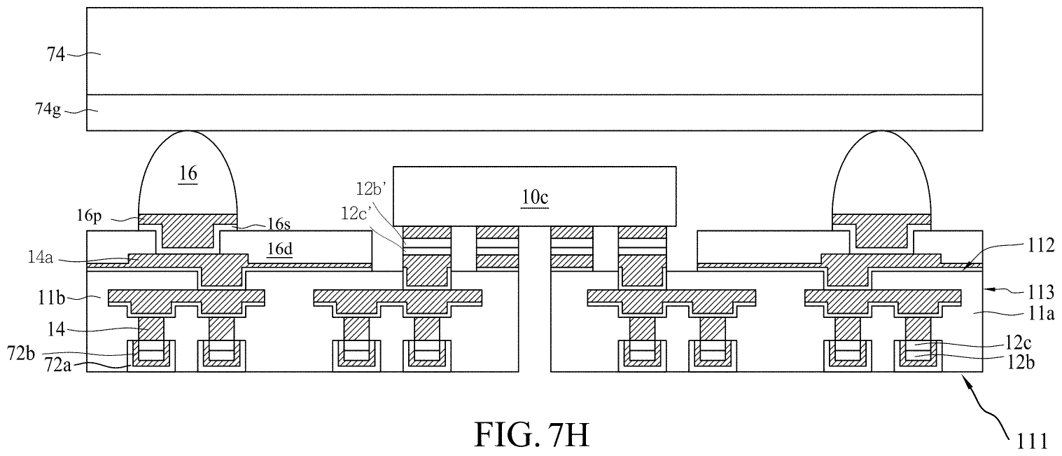

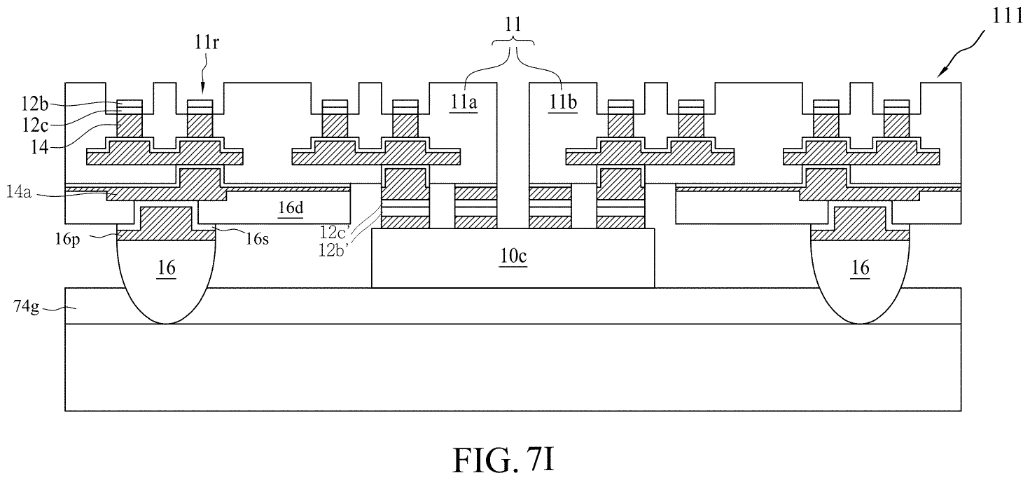

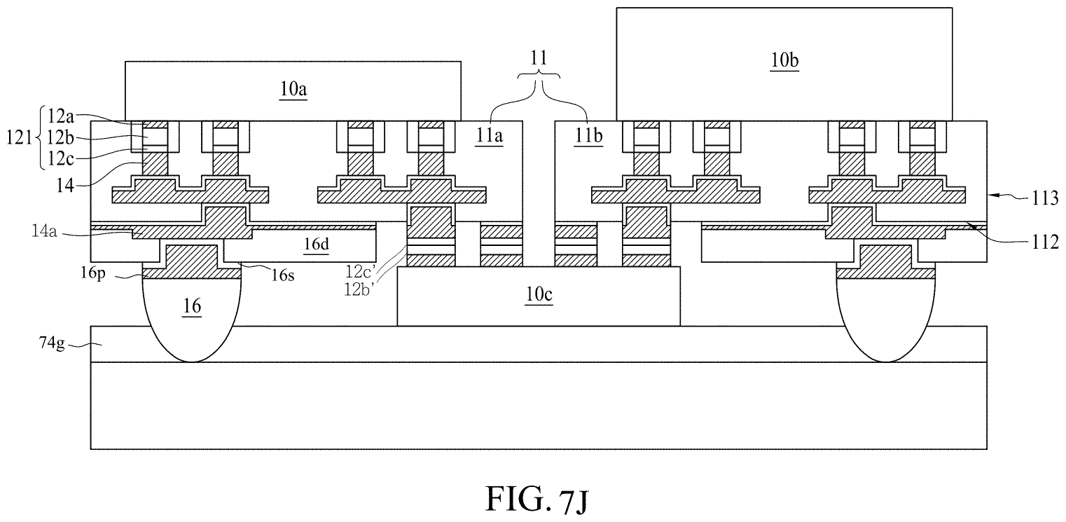

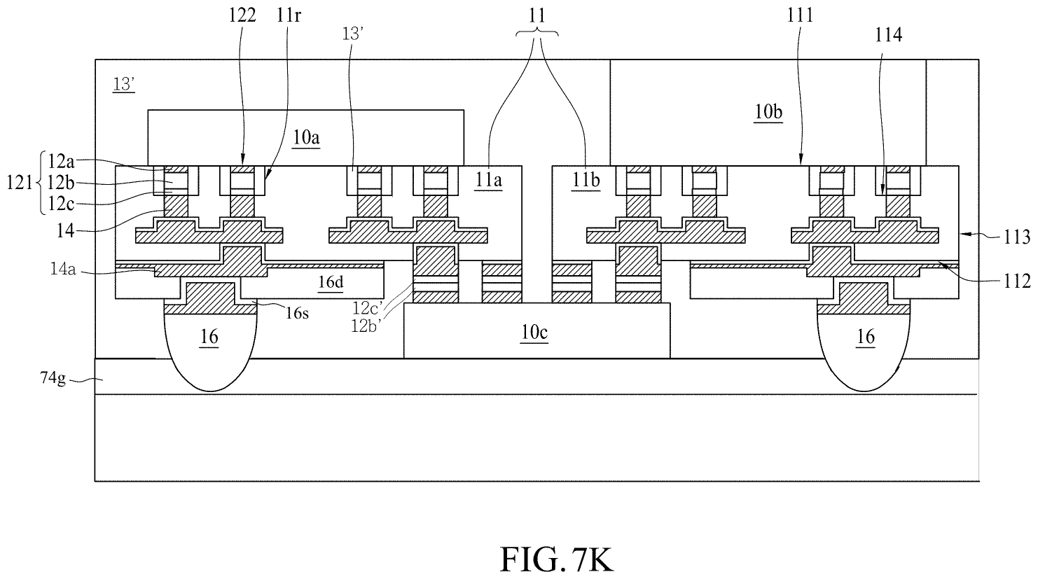

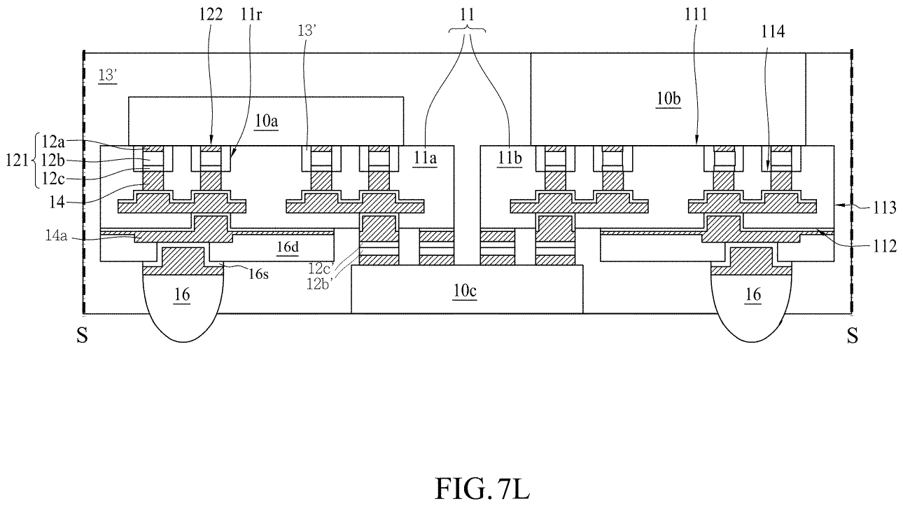

FIG. 7A, FIG. 7B, FIG. 7C, FIG. 7D, FIG. 7E, FIG. 7F, FIG. 7G, FIG. 7H, FIG. 7I, FIG. 7J, FIG. 7K, FIG. and 7L illustrate various stages of a method for manufacturing a semiconductor device package in accordance with some embodiments of the present disclosure. At least some of these figures have been simplified for a better understanding of the aspects of the present disclosure.

Referring to FIG. 7A, a photoresist film 71 (or a mask) can be formed on a carrier 70 by, for example, coating. The photoresist film 71 as shown in FIG. 7A can be disposed on a release layer 70a provided on the carrier 70. A seed layer 70b can be disposed on the release layer 70a by, for example, sputtering.

One or more openings (or trenches) can be formed in the photoresist film 71 by, for example, a lithographic technique, to expose a portion of the seed layer 70b.

A seed layer 72a can be disposed on the sidewalls and bottom surfaces of the openings. In some embodiments, the seed layer 72a is formed by, for example, sputtering titanium and copper (Ti/Cu) or a TiW. In some embodiments, the seed layer 72a may be formed by electroless plating Ni or Cu. Then, a metal layer 72b is formed on the exposed portion of the seed layer 72a by plating Cu, Ag, Ni, Au, or another metal. In some embodiments, the metal layer 72b may be formed by electroless plating Cu, Ni, Pb, or another metal. In some embodiments, the metal layer 72b may be formed by printing Cu, Ag, Au, or another metal.

The seed layer 72a can be conformally disposed in the openings. The metal layer 72b can be conformally disposed in the openings.

Referring to FIG. 7B, a layer 12b can be disposed in the openings and on the metal layer 72b. The layer 12b can be formed by, for example but not limited to, plating Au, Ag, Cu, or another metal. A layer 12c can be disposed in the openings and on the layer 12b. The layer 12c can be formed by, for example but not limited to, plating Ni, Ti, W, or other metal.

The layer 12b can be surrounded by the seed layer 72a in the openings. The layer 12b can be surrounded by the metal layer 72b in the openings.

The layer 12c can be surrounded by the seed layer 72a in the openings. The layer 12c can be surrounded by the metal layer 72b in the openings.

Then a conductive layer 14 can be disposed on the layer 12c by, for example, a lithographic technique.

Referring to FIG. 7C, the photoresist film 71, and the seed layer 72a and the metal layer 72b covering on the photoresist film 71 can be removed by etching or other suitable processes. The remaining structures are the seed layer 72a, the metal layer 72b, the layer 12b, the layer 12c in the original openings, and the conductive layer 14 disposed on the layer 12c, as shown in FIG. 7C.

Referring to FIG. 7D, a dielectric layer 11a and a dielectric layer 11b (collectively referred to as a dielectric layer 11) can be disposed on the seed layer 70b by, for example, coating, lamination or other suitable processes. The dielectric layer 11 can surround the seed layer 72a. The dielectric layer 11 can surround the metal layer 72b. The dielectric layer 11 can surround the conductive layer 14.

Operations of forming the dielectric layers, forming openings in the dielectric layers, and disposing seed layers and metal layers in the openings may be repeated, resulting a structure as illustrated in FIG. 7E.

The dielectric layer 11 can include a surface 111, another surface 112 opposite the surface 111, and a lateral surface 113 extended from the surface 111 to the surface 112. Another conductive layer 14a is disposed and patterned on the surface 112 of the dielectric layer 11.

A layer 12c′ can be disposed on the conductive layer 14a. The layer 12c′ can be the same as or similar to the layer 12c. A layer 12b′ can be disposed on the layer 12c′. The layer 12b′ can be the same as or similar to the layer 12b.

Referring to FIG. 7F, a dielectric layer 16d can be disposed on the surface 112 of the dielectric layer 11. A portion of the conductive layer 14a can be exposed from the dielectric layer 16d, and a portion of the conductive layer 14a can be covered by the dielectric layer 16d. The dielectric layer 16d can be formed by, for example, coating, lamination or other suitable processes.

A conductive pad 16p can be formed on the dielectric layer 16d. The conductive pad 16p can be electrically connected to the conductive layer 14a. In some embodiments, before forming the conductive pad 16p, a seed layer 16s can be disposed on the conductive layer 14a and the dielectric layer 16d.

Referring to FIG. 7G, an electronic component 10c can be attached or bonded to the dielectric layer 11 by mass reflow technique, flip-chip bond technique, or other suitable technique(s). The electronic component 10c can be attached or bonded to the dielectric layer 11 through the layer 12b′ and the layer 12c′.

One or more electrical contact(s) 16 can be attached or bonded to the conductive pad 16p on the dielectric layer 11.

Referring to FIG. 7H, another carrier 74 can be attached to the electrical contact 16 through, for example, glue 74g.

Then, the carrier 70, the release layer 70a, and the seed layer 70b as shown in FIG. 7G can be removed from the dielectric layer 11. After the carrier 70, the release layer 70a, and the seed layer 70b are removed, the seed layer 72a is exposed on the surface 111 of the dielectric layer 11.

Referring to FIG. 7I, the seed layer 72a and the metal layer 72b on the surface 111 of the dielectric layer 11 as shown in FIG. 7H can be removed by etching or other suitable processes. Recesses 11r can be defined in the dielectric layer 11.

Referring to FIG. 7J, electronic components 10a and 10b can be attached or bonded to the dielectric layer 11 by mass reflow technique, flip-chip bond technique or other suitable technique(s). The electronic components 10a and 10b can be attached or bonded to the dielectric layer 11 through a layer 12a disposing on the layer 12b. The layer 12a, the layer 12b, and the layer 12c may form a connection structure (such as the connection structure 121) between the electronic component and the conductive layer 14.

The electronic component 10a can be in direct contact with the surface 111 of the dielectric layer 11. The electronic component 10b can be in direct contact with the surface 111 of the dielectric layer 11.

Referring to FIG. 7K, an insulation material 13′ may be formed to encapsulate the stacked structures as shown in FIG. 7J. The insulation material 13′ can be formed by potting technique, dispensing technique, molding technique or other suitable technique(s). The insulation material 13′ may flow into the recesses 11r. The insulation material 13′ may surround the connection structure (such as the connection structure 121).

Referring to FIG. 7L, a cutting operation or a singulation operation may be performed along the scribe lines S as shown in FIG. 7L to form some individual stacked structures. For example, a cutting operation or a singulation operation may be performed through the insulation material 13′, and each of the individual stacked structure is encapsulated by an encapsulation layer (such as the encapsulation layer 13 in FIG. 1). The cutting operation or singulation operation can be performed by using a dicing saw, laser or other appropriate cutting technique.

The carrier 74 and the glue 74g as shown in FIG. 7K can be removed from the electrical contact 16.

Then a substrate 15 can be attached or bonded to the electrical contact 16, and forming a structure which is the same or similar to the semiconductor device package 1 as illustrated in FIG. 1.

Spatially relative terms, such as “beneath,” “below,” “lower,” “above,” “upper,” “left,” “right” and the like, may be used herein for ease of description to describe one element or feature's relationship to another element(s) or feature(s) as illustrated in the figures. The spatially relative terms are intended to encompass different orientations of the device in use or operation, in addition to the orientation depicted in the figures. The apparatus may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately”, “substantially”, “substantial” and “about” are used to describe and account for small variations. When used in conduction with an event or circumstance, the terms can refer to instances in which the event or circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints unless specified otherwise. The term “substantially coplanar” can refer to two surfaces within micrometers (μm) of lying along the same plane, such as within 10 within 5 within 1 or within 0.5 μm of lying along the same plane. When referring to numerical values or characteristics as “substantially” the same, the term can refer to the values lying within ±10%, ±5%, ±1%, or ±0.5% of an average of the values.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

What is claimed is:

1. A semiconductor device package, comprising:
a dielectric layer having a first surface, a second surface opposite the first surface, and a third surface extended from the first surface to the second surface;
a patterned conductive layer disposed in the dielectric layer;
a first electronic component in direct contact with the first surface of the dielectric layer; and
a first connection structure disposed between the first electronic component and the patterned conductive layer.

2. The semiconductor device package of claim 1, wherein the dielectric layer further comprises a sidewall extended from the first surface toward the second surface, and wherein the first connection structure is spaced apart from the sidewall.

3. The semiconductor device package of claim 2, wherein the first connection structure includes a soldering layer, wherein the soldering layer is spaced apart from the sidewall.

4. The semiconductor device package of claim 3, wherein the soldering layer surrounds a lateral surface of the first connection structure.

5. The semiconductor device package of claim 1, wherein the dielectric layer further comprises a sidewall extended from the first surface toward the second surface, and wherein at least a part of the first connection structure is in contact with the sidewall.

6. The semiconductor device package of claim 1, wherein the dielectric layer further comprises a sidewall extended from the first surface toward the second surface, the sidewall defining a recess, and wherein the first connection structure is disposed in the recess.

7. The semiconductor device package of claim 6, wherein the dielectric layer further comprises a fourth surface substantially parallel to the first surface, the sidewall is extended from the first surface toward the fourth surface.

8. The semiconductor device package of claim 7, wherein the first connection structure is disposed between the first surface and the fourth surface.

9. The semiconductor device package of claim 1, further comprising:
an encapsulation layer surrounding the first connection structure.

10. The semiconductor device package of claim 9, wherein a part of the encapsulation layer is exposed from the first surface of the dielectric layer.

11. The semiconductor device package of claim 10, wherein the exposed portion of the encapsulation layer is in contact with the first electronic component.

12. The semiconductor device package of claim 1, further comprising:
a second electronic component attaching to the second surface of the dielectric layer, wherein a projected area of the first electronic component is shifted from a projected area of the second electronic component.

13. A semiconductor device package, comprising:
a dielectric layer having a first surface, a second surface under the first surface, and a third surface extended from the first surface to the second surface;
a patterned conductive layer disposed in the dielectric layer;
a first electronic component disposed on the first surface of the dielectric layer; and
a first connection structure disposed between the first electronic component and the patterned conductive layer, and disposed between the first surface and the second surface of the dielectric layer.

14. The semiconductor device package of claim 13, further comprising an encapsulation layer encapsulating the first connection structure.

15. The semiconductor device package of claim 13, wherein the patterned conductive layer is exposed by the second surface of the dielectric layer.

16. The semiconductor device package of claim 13, wherein the first electronic component has a surface substantially coplanar with the first surface of the dielectric layer.

17. The semiconductor device package of claim 16, further comprising an encapsulation layer in direct contact with the surface of the first electronic component.

18. The semiconductor device package of claim 13, further comprising an encapsulation layer in direct contact with the third surface of the dielectric layer.

19. A method of manufacturing a semiconductor device package, comprising:
providing a carrier;
forming a seed layer on the carrier;
forming a connection structure on the carrier, the connection structure is surrounded by the seed layer;
forming a dielectric layer on the carrier to surround the seed layer; and
removing the seed layer.

20. The method of claim 19, further comprising:
attaching an electronic component to the connection structure to make the electronic component in direct contact with the dielectric layer.
